(19) United States
(12) Patent Application Publication
(10) Pub. No.: US 2018/0275510 A1
(43) Pub. Date: Sep. 27, 2018

(54) IMPRINTING APPARATUS AND IMPRINTING METHOD

(71) Applicant: TOSHIBA MEMORY CORPORATION, Tokyo (JP)

(72) Inventors: Yoshihisa KAWAMURA, Yokkaichi Mie (JP); Hiroshi TOKUE, Yokohama (JP)

(73) Assignee: TOSHIBA MEMORY CORPORATION, Tokyo (JP)

(21) Appl. No.: 15/696,110

(22) Filed: Sep. 5, 2017

(30) Foreign Application Priority Data
Mar. 24, 2017 (JP) 2017-059460

(51) Int. Cl. G03F 7/00

(52) U.S. Cl. CPC G03F 7/0002

(57) ABSTRACT

An imprinting apparatus includes a substrate holding unit having a first region configured to receive a substrate, and a second region positioned outside a periphery of a first region, the substrate holding unit including a resist removing mechanism including at least one of an exhaust mechanism and an air supply mechanism disposed in the second region. The apparatus further includes a template holding unit configured to hold a template defining recess patterns such that the recess patterns face the substrate holding unit, and such that the template can come into contact with a resist deposited onto the substrate, and one or more nozzles configured to discharge the resist onto the substrate.

### CROSS-REFERENCE TO RELATED APPLICATION

This application claims the benefit of and priority to Japanese Patent Application No. 2017-059460; filed Mar. 24, 2017; the entire contents of which are incorporated herein by reference.

### FIELD

Embodiments described herein relate generally to an imprinting apparatus and an imprinting method.

### BACKGROUND

In some imprinting methods, after a resist is deposited on a workpiece, a template is brought into contact with the resist, the resist is cured, and a mask pattern is formed thereon. In the imprinting methods, however, since the template comes in contact with the resist layer during imprinting of the template, an extrusive resist effuses or flows from an end of the template. When the extrusive resist reaches a next shot region on the workpiece, the next shot may not be imprinted properly. Further, the extrusive resist may be deposited on a mesa (e.g. a protruded platform or surface) portion of the template and fall onto the workpiece, resulting in a potentially undesirable contamination (e.g. a particle source).

### DESCRIPTION OF THE DRAWINGS

FIG. 1 is a cross-sectional view schematically illustrating some embodiments of a configuration of an imprinting apparatus.

FIG. 2 is a top view illustrating some embodiments of a configuration of a substrate stage according to a first aspect.

FIG. 3 is a partial top view illustrating some embodiments of the configuration of the substrate stage according to the first aspect.

FIG. 4 is a partial cross-sectional view illustrating some embodiments of the configuration of the substrate stage according to the first aspect.

FIG. 5 is a flowchart illustrating an example of steps of some embodiments of an imprinting method according to the first aspect.

FIG. 6 is a partial cross-sectional view illustrating some embodiments of a configuration of a substrate stage according to a second aspect.

FIG. 7 is a flowchart illustrating an example of steps of some embodiments of an imprinting method according to the second aspect.

FIG. 8 is a partial cross-sectional view illustrating some embodiments of a configuration of a substrate stage according to a third aspect.

FIG. 9 is a partial enlarged view illustrating some embodiments of the configuration of the substrate stage according to the third aspect.

FIG. 10 is a flowchart illustrating an example of steps of some embodiments of an imprinting method according to the third aspect.

FIG. 11 is a top view illustrating some embodiments of a configuration of a substrate stage according to a fourth aspect.

FIG. 12 is a partial cross-sectional view illustrating some embodiments of the configuration of the substrate stage according to the fourth aspect.

FIG. 13 is a top view illustrating some embodiments of a configuration of a substrate stage according to a fifth aspect.

FIG. 14 is a partial cross-sectional view illustrating some embodiments of the configuration of the substrate stage according to the fifth aspect.

FIG. 15A and FIG. 15B are partial cross-sectional views schematically illustrating states at a time of an imprinting process according to a comparative example.

FIG. 16 is a diagram illustrating some embodiments of a hardware configuration of a controller.

### DETAILED DESCRIPTION

Example embodiments described herein provide for an imprinting apparatus and an imprinting method capable of removing a resist deposited on a mesa portion of a template by effusing.

In some embodiments according to a first aspect, an imprinting apparatus includes a substrate holding unit having a first region configured to receive a substrate, and a second region positioned outside a periphery of a first region, the substrate holding unit including a resist removing mechanism including at least one of an exhaust mechanism and an air supply mechanism disposed in the second region. The apparatus further includes a template holding unit configured to hold a template defining recess patterns such that the recess patterns face the substrate holding unit, and such that the template can come into contact with a resist deposited onto the substrate, and one or more nozzles configured to discharge the resist onto the substrate.

In some embodiments according to another aspect, an imprinting method includes placing a substrate on a substrate holding unit, the substrate holding unit having a first region configured to receive a substrate and a second region positioned outside a periphery of the first region. The imprinting method further includes depositing a resist onto the substrate, causing a template defining recess patterns to contact the resist, and using a resist removing mechanism including at least one of an exhaust mechanism and an air supply mechanism provided in the second region to remove a portion of the deposited resist that is positioned on the template facing the second region.

In some embodiments according to another aspect, an imprinting method includes placing a substrate on a substrate holding unit, the substrate holding unit having a first region configured to receive a substrate and a second region positioned outside a periphery of the first region. The imprinting method further includes depositing a resist onto the substrate, and causing a template defining recess patterns that are disposed at least in part in the second region to contact the resist. The imprinting method further includes generating a laminar flow of a gas along a surface of the template and a side surface of the substrate in the second region, substantially filling the recess patterns with the resist while maintaining the laminar flow, and irradiating the resist filled in the recess patterns with ultraviolet rays while maintaining the laminar flow.

An imprinting apparatus and an imprinting method according to some embodiments will be described below in detail with reference to accompanying drawings. It is noted that the present disclosure is not intended to be limited to the explicitly described embodiments. Additionally, the depicted schematic cross-sectional view of imprinting apparatuses, and relations between a thickness and a width of components, a ratio of thicknesses between the components, or the like may be different from those of actually implemented components.

### First Aspect

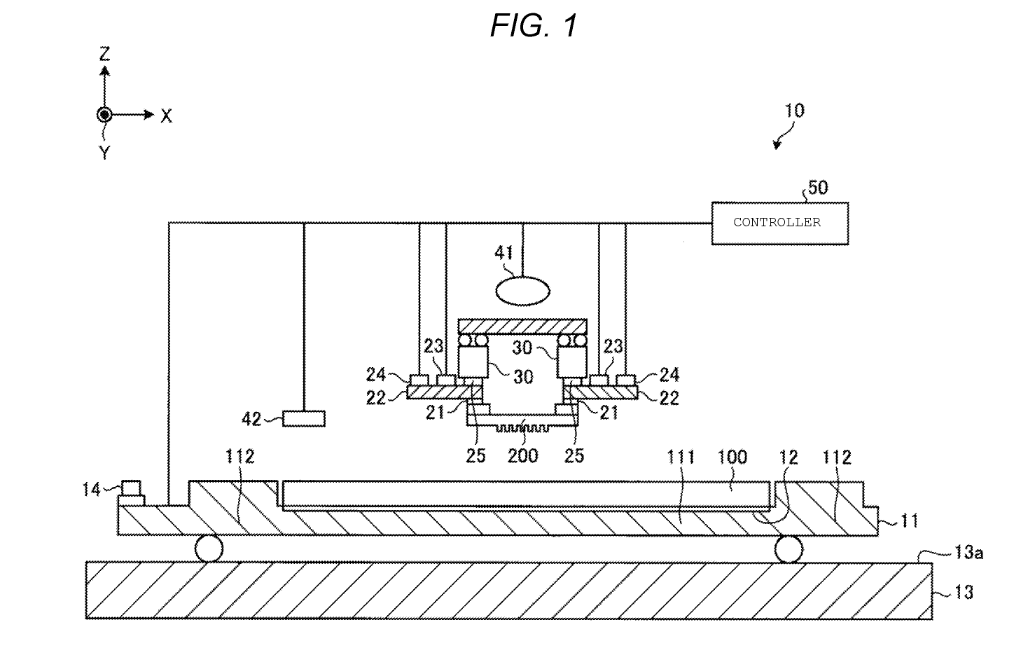

FIG. 1 is a sectional view schematically illustrating some embodiments of a configuration of an imprinting apparatus according to a first aspect. An imprinting apparatus 10 includes a substrate stage 11 that holds a substrate 100. The substrate stage 11 includes a substrate placing region 111 and a substrate periphery region 112. The substrate placing region 111 is a region on which the substrate 100 is placed. The substrate placing region 111 has substantially the same size as the substrate 100 when viewed from a plan view. In the substrate placing region 111, a chuck 12 is provided. The chuck 12 holds the substrate 100 on which a pattern is formed. The chuck 12 holds the substrate 100 through, for example, vacuum suction. The substrate periphery region 112 is provided to surround the outside of the substrate placing region 111. An upper surface of the substrate periphery region 112 is positioned higher than an upper surface of the substrate placing region 111 by a thickness of the substrate 100. That is, when the substrate 100 is placed on the substrate stage 11, the position of the upper surface of the substrate 100 substantially coincides with the position of the upper surface of the substrate periphery region 112. The substrate stage 11 and the chuck 12 can constitute at least part of a substrate holding unit.

The substrate 100 is a substrate (wafer) such as a semiconductor substrate, or a substrate formed with an underlying pattern and a layer to be processed formed on the underlying pattern, and/or a substrate to which a pattern is to be transferred. The substrate further includes a resist formed on the layer to be processed, when a pattern is transferred. The layer to be processed includes an insulating film, a metal film (conductive film), or a semiconductor film.

The substrate stage 11 is movably provided (e.g. is configured to be movable) on a stage surface-plate 13. The substrate stage 11 is configured to be movable along two axes parallel to and provided on an upper surface 13a of the stage surface-plate 13. Here, the two axes provided on the upper surface 13a of the stage surface-plate 13 are referred to as an X-axis and a Y-axis. Further, the substrate stage 11 is also provided movably along a Z-axis that is a height direction orthogonal to the X-axis and the Y-axis. Preferably, the substrate stage 11 is provided rotatably around the X-axis, the Y-axis, and the Z-axis.

The substrate stage 11 is provided with a reference mark table 14. A reference mark (not illustrated) serving as a reference position of the imprinting apparatus 10 is installed on the reference mark table 14. The reference mark is constituted by a checkered diffraction grating, for example. The reference mark is used for calibration of an alignment sensor 30 and positioning (posture control or adjustment) of a template 200. The reference mark is referred to as an origin on the substrate stage 11. X and Y coordinates of the substrate 100 placed on the substrate stage 11 are coordinates with respect to the reference mark table 14 serving as an origin.

The imprinting apparatus 10 includes a template stage 21. The template stage 21 fixes a template (which may be referred to as an “original plate,” or a “mold”) 200. The template stage 21 holds a periphery (e.g. a circumferential edge portion) of the template 200, for example, by vacuum suction. The template stage 21 operates to position the template 200 on a reference position of the apparatus. The template stage 21 is mounted to a base portion 22.

The base portion 22 is mounted with a correction mechanism 23 and a pressurizing unit 24. The correction mechanism 23 includes an adjustment mechanism for finely adjusting the position (posture) of the template 200, for example, responsive to receiving an instruction from a controller 50. Thereby, the relative position between the template 200 and the substrate 100 is corrected.

The pressurizing unit 24 applies stress to the side of the template 200 to calibrate distortion of the template 200. The pressurizing unit 24 pressurizes the template 200 from four sides of the template 200 toward the center. Thereby, the size of the pattern to be transferred can be corrected (magnification correction). The pressurizing unit 24 is configured to receive an instruction from the controller 50, for example, and to responsively pressurize the template 200 with a predetermined stress.

The base portion 22 is mounted to an alignment stage 25. In order to align the template 200 and the substrate 100, the alignment stage 25 moves the base portion 22 in the X-axis direction and the Y-axis direction. The alignment stage 25 also has a function of rotating the base portion 22 along an XY plane. The direction of rotation along the XY plane is referred to as a θ direction. A template holding unit includes the template stage 21, and may additionally include the base portion 22, the correction mechanism 23, the pressurizing unit 24, and the alignment stage 25.

An alignment scope 30 detects alignment marks provided on the template 200 and alignment marks provided on the substrate 100. The alignment marks on the template 200 and the alignment marks on the substrate 100 are used to measure a relative position deviation between the template 200 and the substrate 100. As shown in FIG. 1, two alignment scopes 30 are disposed on the right and left sides, but it is preferable that four or more alignment scopes are disposed.

The imprinting apparatus 10 includes a light source 41 and a coating unit 42. The light source 41 emits electromagnetic waves in a ultraviolet range, for example. The light source 41 is installed immediately above the template 200, for example. In other embodiments, the light source 41 is not installed immediately above the template 200. In such embodiments, an optical path is set using an optical member such as a mirror so that light emitted from the light source 41 is irradiated toward the template 200 from immediately above the template 200.

The coating unit 42 is configured to apply a resist onto the substrate 100. For example, the coating unit 42 includes one or more nozzles, and deposits the resist from the one or more nozzles onto the substrate 100.

The imprinting apparatus 10 includes a controller 50. The controller 50 can be configured to control the entire imprinting apparatus 10. For example, the controller 50 executes, for example, one or more machine-readable instructions or programs stored in a computer memory, and responsively performs a corresponding process, including any of a control process of the substrate stage 11, a control process of the light source 41, a position deviation correcting process, a template height operating process, and a magnification correction process.

The control process of the substrate stage 11 includes a process of generating a signal for controlling the substrate stage 11 in the X-axis direction, the Y-axis direction, the Z-axis direction, and the θ direction. Thus, the relative position between the template 200 and the substrate stage 11 is controlled. The control process of the light source 41 includes a process of controlling irradiation timing or the amount of light to be irradiated by the light source 41 when the resist is cured.

The position deviation correcting process is performed using the alignment mark of the template 200, the reference mark of the reference mark table 14 or the alignment mark of the substrate 100 to obtain the position deviation of the template 200 with respect to the reference mark and the position deviation of the substrate 100 with respect to the template 200. In the position deviation correcting process, an arithmetic operation can be performed as part of a process to align the template stage 21 and the substrate stage 11 based on these position deviations, thereby correcting the position deviation.

The template height operating process includes selecting or setting a template height at a formation position of the alignment mark of the template 200 using the alignment mark of the template 200, the reference mark of the reference mark table 14 or the alignment mark of the substrate 100.

The magnification correction process includes performing a predetermined arithmetic operation based on the template height and calculating a stress for magnification correction of the template 200, and transmitting a signal for generating this stress to the pressurizing unit 24.

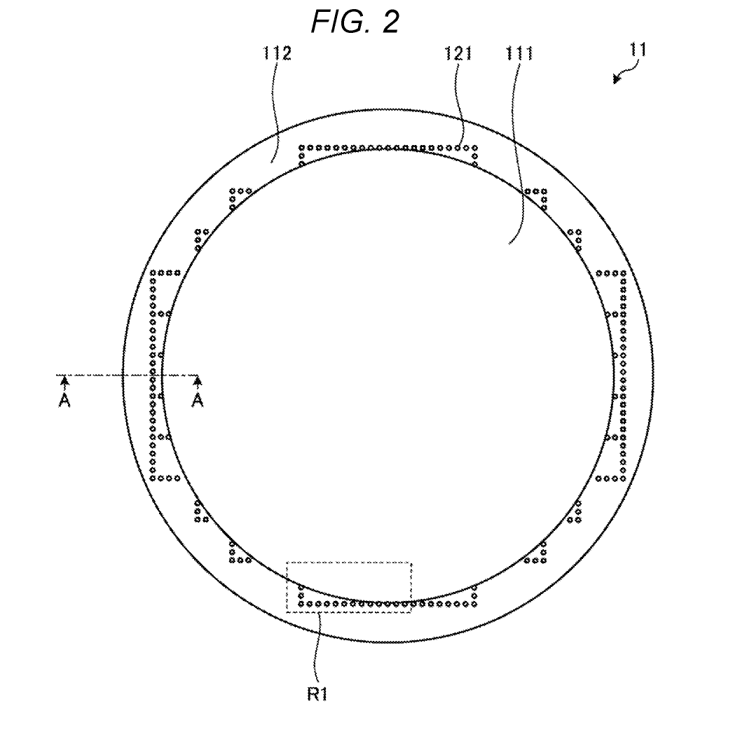

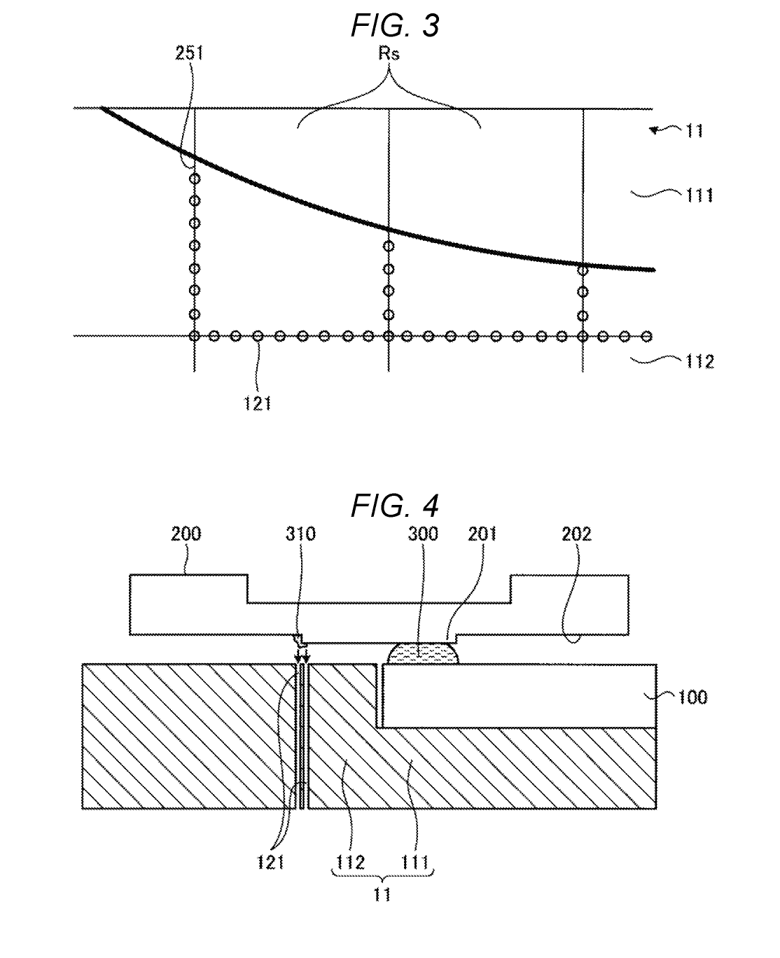

FIG. 2 is a top view illustrating some embodiments of a configuration of the substrate stage according to the first aspect. FIG. 3 is a partial top view illustrating some embodiments of the configuration of the substrate stage according to the first aspect, and is an enlarged view of a region R1 shown in FIG. 2. FIG. 4 is a partial cross-sectional view illustrating some embodiments of the configuration of the substrate stage according to the first aspect, and is a cross-sectional view taken along line A-A shown in FIG. 2. In FIG. 4, the template 200 is drawn as well for convenience of explanation.

The template 200 used in the imprinting method includes a mesa portion 201 where a recess pattern is formed and an off-mesa portion 202 which is a region other than the mesa portion 201. The mesa portion 201 has a mesa structure, and protrudes by several tens of micrometers (μm) from the off-mesa portion 202. The mesa portion 201 comes in contact with a resist 300 on the substrate 100 when the template 200 is imprinted. A region at which the substrate 100 or the substrate stage 11 comes in contact with the mesa portion 201 during the imprinting process is referred to as a shot region Rs. The template 200 includes a material such as quartz or fluorite that allows at least some ultraviolet rays to pass through.

The shot region Rs can be near the center of the substrate 100 and entirely within the substrate 100. However, a part of the shot region Rs can be near an outer periphery of the substrate 100, and can extend from the substrate 100 to the substrate stage 11 (referred to as “overflowing”). A shot for which the imprint extends beyond the substrate 100 in this way is referred to as a “partial shot.” The position of the shot region Rs is determined in advance on the substrate 100 held in the substrate stage 11. Therefore, the position of a partial shot region Rs is also determined in the substrate periphery region 112 of the substrate stage 11.

According to the first aspect, as shown in FIG. 2 and FIG. 3 exhaust holes 121 are provided along an outer periphery 251 of the shot region Rs (e.g. a portion of the shot region Rs overflowing into the substrate periphery region 112 of the substrate stage 11). In this example, the exhaust holes 121 are provided to penetrate the substrate stage 11 in a thickness direction. For example, the exhaust holes 121 each having a diameter of about 0.5 millimeters (mm) are provided along the outer periphery 251 of the shot region Rs with an interval of about 1 mm. The exhaust holes 121 are connected to an exhaust unit such as a vacuum pump (not illustrated) on a surface opposite to the surface on which the template 200 is disposed. An exhaust speed can be set, for example, in a range of about 3 to about 30 liters (L) per minute (min). According to the first aspect, an exhaust mechanism includes the exhaust hole 121 and the exhaust unit. In addition, a resist removing mechanism includes the exhaust mechanism.

With such a structure, when the template 200 is brought into contact with the resist 300 on the substrate 100 in a partial shot region Rs, a deposit 310, for example, the resist effusing into the substrate periphery region 112 from the substrate 100 or the resist deposited on an end of the mesa portion 201 of the template 200 can be sucked by a suction force from the exhaust unit. For example, when the deposit 310 is not solidified, a gas volatilizing from the deposit 310 is sucked. Further, when the deposit 310 is solidified, the deposit 310 is pulled off from the template 200 by the suction force from the exhaust unit, and sucked from exhaust hole 121. Thus, the deposit 310 adhering onto the template 200 is removed.

Furthermore, since the exhaust holes 121 are provided along the periphery of the shot region Rs in the substrate periphery region 112, an end of the mesa portion 201 is sucked by the suction force from the exhaust hole 121. As a result, the deposit 310 readily adhering to the end of the mesa portion 201 can fall from the template 200, and can be sucked from the exhaust hole 121.

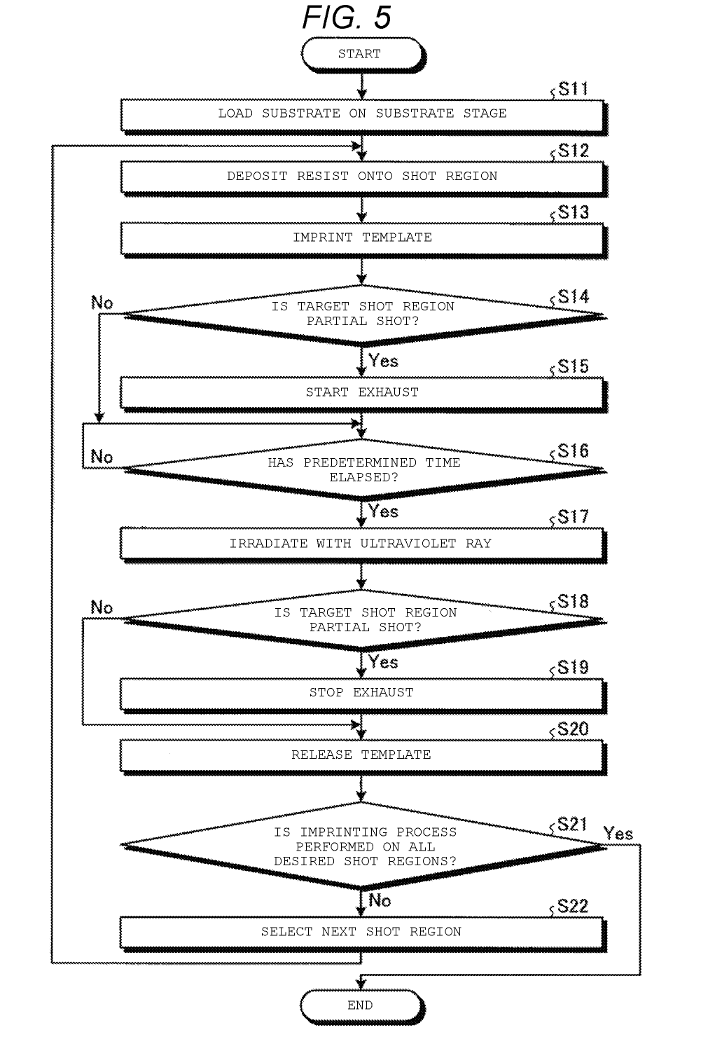

Next, description will be given with respect to an imprinting method using the imprinting apparatus 10. FIG. 5 is a flowchart illustrating some steps of some embodiments the imprinting method according to the first aspect. First, the substrate 100 is loaded on the substrate stage 11 of the imprinting apparatus 10 (step S11). Subsequently, the resist 300 is deposited onto the target shot region Rs of the substrate 100 by an inkjet method (step S12). When the shot region Rs is a partial shot, at least a portion of the resist 300 is deposited onto the shot region Rs of the substrate periphery region 112.

Thereafter, the template 200 is lowered and brought into contact with the resist 300 on the substrate 100, thereby being imprinted thereon (step S13). In the imprinting process of the resist 300, an alignment process is also performed. Next, it is determined whether the target shot region Rs is a partial shot (step S14). When the target shot region Rs is a partial shot (Yes in step S14), the exhaust is performed (step S15) from the exhaust holes 121 provided in the substrate periphery region 112 of the substrate stage 11 of the substrate 100 when the imprinting process of the resist 300 is started. The exhaust is performed, for example, from the exhaust holes 121 at a flow rate of about 20 L/min. Since the end of the mesa portion 201 of the template 200 is located immediately above the exhaust hole 121, it is possible to suck the deposit 310 such as the resist 300 effusing on to the end of the mesa portion 201.

Alternatively, when it is determined in step S14 that the target shot region Rs is not a partial shot (No in step S14), the process can skip to step S16, and it is determined whether a predetermined time has elapsed (step S16). The predetermined time is set to be longer than a time required for filling the resist 300 between the patterns of the template 200. When the predetermined time has not elapsed (No in step S16), the process waits until the predetermined time has elapsed.

When the predetermined time has elapsed (Yes in step S16), the resist 300 is irradiated with ultraviolet rays (step S17). Thus, the resist 300 imprinted with the template 200 is cured. Thereafter, it is determined whether the target shot region Rs is a partial shot (step S18). When the target shot region Rs is a partial shot (Yes in step S18), the exhaust from the exhaust holes 121 is stopped (step S19).

Alternatively, when it is determined in step S18 that the target shot region Rs is not a partial shot (No in step S18), the process may skip to step S20 and the template 200 is released from the substrate 100 (step S20). Subsequently, it is determined whether the imprinting process has been performed on all desired shot regions Rs (step S21). When the imprinting process has not been performed on all desired shot regions Rs (No in step S21), a next shot region Rs is selected (step S22), and the process returns to step S12. Further, when the imprinting process has been performed on all desired shot region Rs (Yes in step S21), the process is ended.

In some embodiments according to the first aspect, the exhaust holes 121 are provided along the outer periphery 251 of the shot region Rs on the substrate periphery region 112 of the imprinting apparatus 10, and the exhaust is performed through the exhaust holes 121 at the time of imprinting the template 200. Thus, at the time of imprinting the template 200 involving a partial shot, it is possible to suck the resist 300 effusing into the end of the mesa portion 201 overflowing into the substrate periphery region 112. Further, the deposit 310 adhering to the end of the mesa portion 201 can fall onto the substrate stage 11, and the fallen deposit 310 can be sucked away. Particularly, it is possible to suck the deposit 310 hanging halfway at the end of the mesa portion 201 or the deposit 310 including the resist, which may not readily adhere. As a result, it is possible to prevent the resist 300 from effusing into the adjacent shot region Rs during the imprinting, and it is also possible to prevent the extrusive resist 300 from being deposited on the mesa portion 201 of the template 200 and falling onto the workpiece, resulting in a contamination (e.g. a particle source).

### Second Aspect

The embodiments described above according to the first aspect include the exhaust holes provided along the outer periphery of the shot region Rs provided in the substrate periphery region of the substrate stage. Embodiments are described below according to a second aspect in which air supply holes are provided along an outer periphery of a shot region in a substrate periphery region.

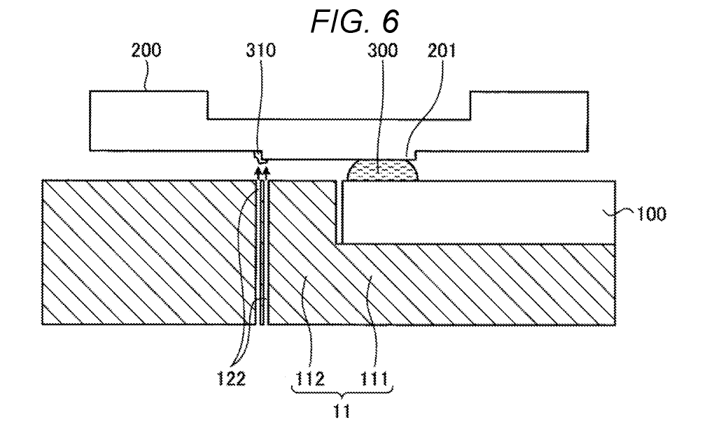

FIG. 6 is a partial cross-sectional view illustrating some embodiments of a configuration of a substrate stage according to the second aspect. In the configuration of an imprinting apparatus 10 according to the second embodiment, the exhaust holes 121 of the first embodiment are replaced by air supply holes 122. An example of a gas to be used may include ozone (O₃), air, oxygen, nitrogen, helium (He), or argon (Ar). Further, an air supply speed can be set, for example, in a range of about 3 to about 30 L/min. According to the second aspect, the air supply mechanism includes the air supply hole 122. A resist removing mechanism includes the air supply mechanism.

With such a structure, when the template 200 is imprinted on a resist 300 on a partial shot region of the substrate 100, the gas supplied from the air supply hole 122 can be blown to a deposit 310, for example, a resist effusing into a substrate periphery region 112 from the substrate 100 or an uncured resist deposited on an end of a mesa portion 201 of the template 200. As a result, the deposit 310 can be volatilized. When ozone is used as the gas, the resist 300 is decomposed into hydrocarbons and becomes a gas due to a chemical reaction of radicals contained in the ozone.

The same components as those of the first aspect are denoted by the same reference numerals, and the details thereof will not be presented.

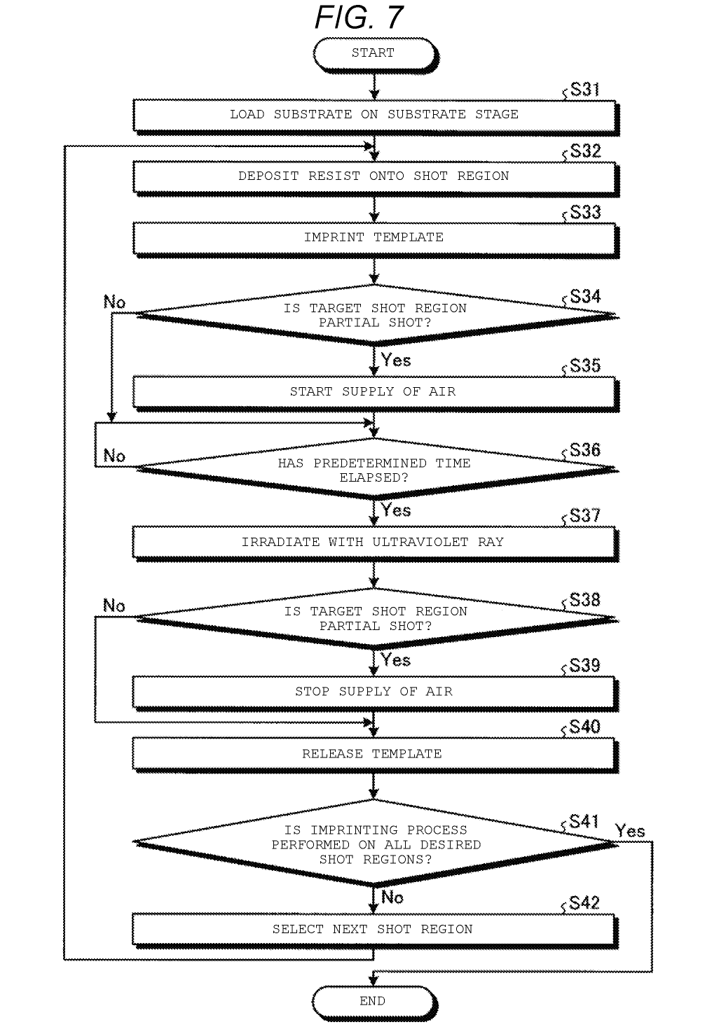

Embodiments of an imprinting method according to the second aspect will be described below. Here, ozone is used as an example of a supply gas. FIG. 7 is a flowchart illustrating embodiments of steps in the imprinting method according to the second aspect. Similarly to steps S11 to S14 shown in FIG. 5 of the first aspect, the substrate 100 is loaded on the substrate stage 11 of the imprinting apparatus 10, the resist 300 is deposited onto the shot region Rs, the template 200 is lowered to be imprinted on the resist 300, and it is determined whether the target shot region Rs is a partial shot (steps S31 to S34).

When the target shot region Rs is a partial shot (Yes in step S34), the ozone gas is supplied (step S35) from the air supply hole 122 provided in the substrate periphery region 112 of the substrate stage 11 of the substrate 100 when the imprinting process of the resist 300 is started. The ozone gas is supplied, for example, from the air supply hole 122 at a flow rate of about 20 L/min. Since the end of the mesa portion 201 of the template 200 is located immediately above the air supply hole 122, the ozone gas can be blown to the resist 300 effusing into the end of the mesa portion 201.

Alternatively, when it is determined in step S34 that the target shot region Rs is not a partial shot (No in step S34), the process can skip to step S36 and it is determined whether a predetermined time has elapsed (step S36). The predetermined time is set to be longer than a time required for filling the resist 300 between the patterns of the template 200. While the predetermined time has not elapsed (No in step S36), the process waits until the predetermined time has elapsed.

When the predetermined time has elapsed (Yes in step S36), the resist 300 is irradiated with ultraviolet rays (step S37). Thus, the resist 300 is cured. At this time, when ultraviolet rays having a wavelength of, for example, about 254 nm are irradiated, the ozone gas is decomposed, and excited active oxygen O⁻ (an oxygen ion) is generated. When gas other than oxygen is implemented, the wavelength of the rays may be adjusted accordingly. The active oxygen O⁻ bonds to the component of the resist 300 adhering to the mesa portion 201 of the template 200, thereby becoming a gas such as carbon dioxide (CO₂).

Thereafter, it is determined whether the target shot region Rs is a partial shot (step S38). When the target shot region Rs is a partial shot (Yes in step S38), the supply of the ozone gas from the air supply hole 122 is stopped (step S39).

Alternatively, when it is determined in step S38 that the target shot region Rs is not a partial shot (No in step S38), the process can skip to step S40 and the template 200 is released from the substrate 100 (step S40). Subsequently, it is determined whether the imprinting process has been performed on all desired shot regions Rs (step S41). When the imprinting process has not been performed on all desired shot regions Rs (No in step S41), the next shot region Rs is selected (step S42), and the process returns to step S32. Further, when the imprinting process is performed on all desired shot regions Rs (Yes in step S41), the process is ended.

In the above description, the gas to be supplied from the air supply hole 122 is ozone, but other gases may be supplied. The gas to be supplied may be, for example, air, oxygen, nitrogen, He, or Ar. In this case, the resist 300 effusing into the end of the template 200 is volatilized by the gas blown when the template 200 is imprinted in the partial shot region, for example.

In the second aspect, the air supply hole 122 is provided along the outer periphery 251 of the shot region Rs of the substrate periphery region 112, and the gas is supplied from the air supply hole 122 during the imprinting of the template 200. Thereby, during the imprinting of the template 200 in the partial shot, the deposit 310, for example, the resist 300 effusing into the end of the mesa portion 201 or the uncured resist 300 deposited on the end of the mesa portion 201 of the template 200 is readily volatilized. The excited active oxygen is generated using the ozone when the ultraviolet rays are irradiated, and the component of the resist 300 adhering to the mesa portion 201 is decomposed into CO₂ by the active oxygen. As a result, it is possible to prevent the resist 300 from effusing into the adjacent shot region Rs during the imprinting, and it is also possible to prevent the extrusive resist 300 from being deposited on the mesa portion 201 of the template 200 and falling onto the workpiece, resulting in a contamination (e.g. a particle source).

### Third Aspect

Embodiments according to the first aspect in which the exhaust holes are provided along the outer periphery of the shot region provided in the substrate periphery region of the substrate stage, and embodiments according to the second aspect in which the air supply holes are provided along the outer periphery of the shot region in the substrate periphery region have been described. According to a third aspect, embodiments will be described in which exhaust holes and air supply holes are provided along an outer periphery of a shot region of a substrate periphery region.

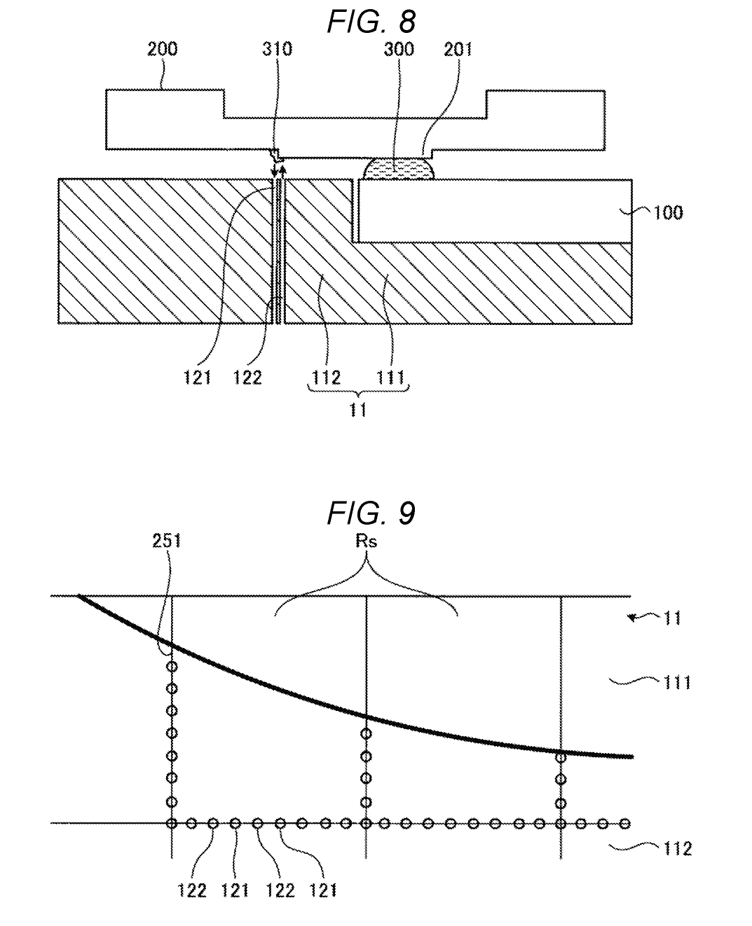

FIG. 8 is a partial cross-sectional view illustrating some embodiments of a configuration of a substrate stage according to the third aspect, and FIG. 9 is a partial top view illustrating some embodiments of the configuration of the substrate stage according to the third aspect. In FIG. 8, a template 200 is drawn as well for convenience of explanation. In the configuration of an imprinting apparatus 10 according to the third aspect, the exhaust holes 121 of the first aspect are replaced by exhaust holes 121 and air supply holes 122. In this example, the exhaust holes 121 and the air supply holes 122 are, for example, alternately provided, along an outer periphery 251 of a shot region Rs overflowing into a substrate periphery region 112. In other embodiments, the exhaust holes 121 and the air supply holes 122 need not be alternately provided, and may be provided in any other appropriate manner.

The exhaust holes 121 are provided to penetrate a substrate stage 11 in a thickness direction. Then, the exhaust holes 121 are connected to an exhaust unit such as a vacuum pump (not illustrated) on a surface opposite to the surface on which the template 200 is disposed. An exhaust speed can be set, for example, in a range of about 3 to about 30 L/min.

The air supply holes 122 are provided to penetrate the substrate stage 11 in the thickness direction. An example of a gas to be used may include ozone, air, oxygen, nitrogen, He, or Ar. Further, an air supply speed can be set, for example, in a range of about 3 to about 30 L/min. In the third aspect, an exhaust mechanism includes the exhaust holes 121 and the exhaust unit, and an air supply mechanism includes the air supply hole 122. A resist removing mechanism includes the exhaust mechanism and the air supply mechanism.

With such a structure, when the template 200 is imprinted on a resist 300 on a partial shot region of the substrate 100, a gas supplied from the air supply hole 122 is blown to a deposit 310, for example, a resist effusing into a substrate periphery region 112 from the substrate 100 or an uncured resist deposited on an end of a mesa portion 201 of the template 200. When the deposit 310 is the uncured resist, the deposit 310 can be volatilized by the blowing of the gas. In addition, when ozone is used as the gas, the resist 300 is decomposed into hydrocarbons to become a gas due to a chemical reaction of radicals contained in the ozone. At this time, the volatilized component or the gas generated by the decomposition of the resist 300 is exhausted from the exhaust holes 121. Alternatively, the deposit 310 is peeled off from the mesa portion 201 by a physical force (e.g. a physical force caused by the gas supplied from the air supply holes 122). The peeled deposit 310 is discharged to the exhaust holes 121. In this way, the resist 300 adhering to the template 200 is removed.

The same components as those of the first and second aspects are denoted by the same reference numerals, and the details thereof will not be presented.

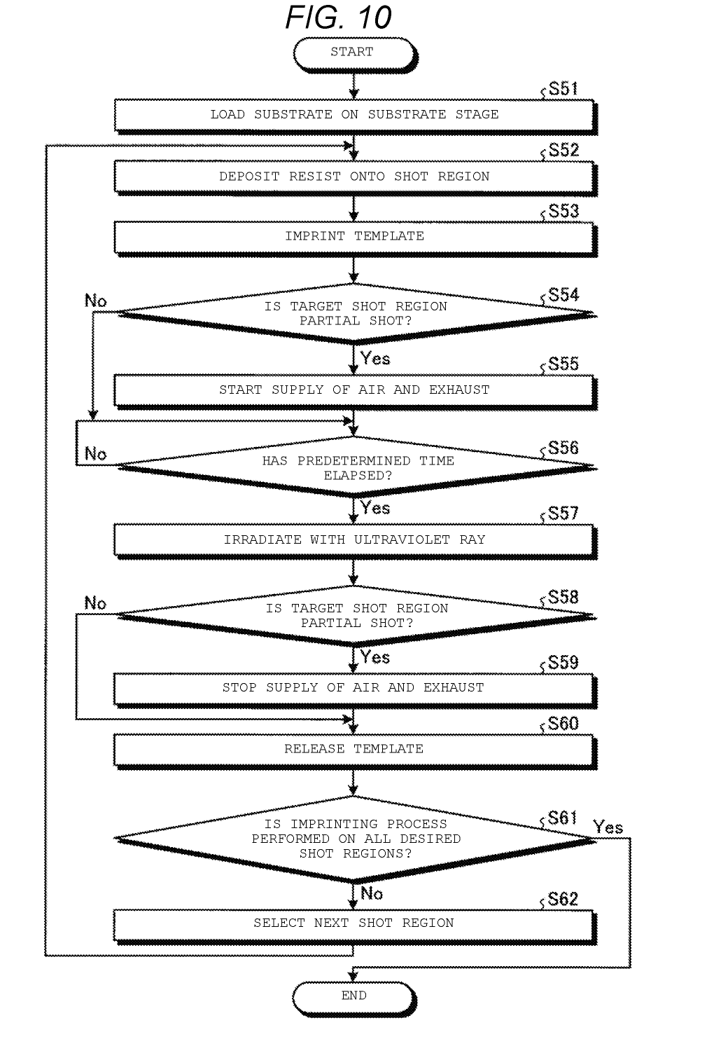

An imprinting method according to the third aspect will be described below. Here, ozone is used as an example of a supply gas. FIG. 10 is a flowchart illustrating some steps of some embodiments of the imprinting method according to the third aspect. Similarly to steps S11 to S14 shown in FIG. 5 of the first aspect, the substrate 100 is loaded on the substrate stage 11 of the imprinting apparatus 10, the resist 300 is deposited onto the shot region Rs, the template 200 is lowered to be imprinted on the resist 300, and it is determined whether the target shot region Rs is a partial shot (steps S51 to S54).

When the target shot region Rs is the partial shot (Yes in step S54), the ozone gas is supplied from the air supply hole 122 provided in the substrate periphery region 112 of the substrate stage 11 of the substrate 100 and the exhaust is performed from the exhaust holes 121 (step S55) when the imprinting process of the resist 300 is started. The ozone gas is supplied, for example, from the air supply hole 122 at a flow rate of about 20 L/min. Since the end of the mesa portion 201 of the template 200 is located immediately above the air supply hole 122, the ozone gas can be blown to the resist 300 effusing into the end of the mesa portion 201. In addition, the exhaust is performed at a flow rate of, for example, about 20 L/min from the exhaust holes 121. Since the end of the mesa portion 201 of the template 200 is located immediately above the exhaust hole 121, the resist 300 effusing into the end of the mesa portion 201 can be sucked, the volatilized component can be exhausted by the blowing of the ozone gas, or the effused component of the resist 300 can be discharged by the blowing of the ozone gas.

Alternatively, when it is determined in step S54 that the target shot region Rs is not a partial shot (No in step S54), the process can skip to step S56 and it is determined whether a predetermined time has elapsed (step S56). The predetermined time is set to be longer than a time required for filling the resist 300 between the patterns of the template 200. While the predetermined time has not elapsed (No in step S56), the process waits until the predetermined time has elapsed.

When the predetermined time has elapsed (Yes in step S56), the resist 300 is irradiated with ultraviolet rays (step S57). Thus, the resist 300 is cured. At this time, when ultraviolet rays having a wavelength of about 254 nm are irradiated, the ozone gas is decomposed, and excited active oxygen O⁻ is generated. When gas other than oxygen is implemented, the wavelength of the rays may be adjusted accordingly. The active oxygen O⁻ bonds to the component of the resist 300 adhering to the mesa portion 201 of the template 200, thereby becoming a gas such as CO₂. The gas such as CO₂ is removed from the exhaust hole 121.

Thereafter, it is determined whether the target shot region Rs is a partial shot (step S58). When the target shot region Rs is the partial shot (Yes in step S58), the supply of the ozone gas from the air supply hole 122 is stopped and the exhaust from the exhaust hole 121 is stopped (step S59).

Alternatively, when it is determined in step S58 that the target shot region Rs is not a partial shot (No in step S58), the process can skip to step S60 and the template 200 is released from the substrate 100 (step S60). Subsequently, it is determined whether the imprinting process is performed on all desired regions Rs (step S61). When the imprinting process is not performed on all desired shot regions Rs (No in step S61), the next shot region Rs is selected (step S62), and the process returns to step S52. Further, when the imprinting process is performed on all desired shot regions Rs (Yes in step S61), the process is ended.

In the above description, the gas to be supplied from the air supply hole 122 is ozone, but other gases may be supplied. The gas to be supplied may be, for example, air, oxygen, nitrogen, He, or Ar. In this case, the resist 300 effusing into the end of the template 200 is likely to be volatilized by the gas to be blown when the template 200 is imprinted, for example. Further, the deposit 310 exhausted by blowing can be discharged from the exhaust hole 121.

In the third aspect, the air supply holes 122 and the exhaust holes 121 are alternatively provided along the outer periphery 251 of the shot region Rs of the substrate periphery region 112, and the gas is supplied from the air supply holes 122 and is exhausted from the exhaust holes 121 during the imprinting of the template 200. Thereby, during the imprinting of the template 200 in the partial shot, the resist 300 effusing into the end of the mesa portion 201 is readily volatilized, and the volatilized component can be exhausted without diffusing into the ambient atmosphere. The excited active oxygen is generated using the ozone when the ultraviolet rays are irradiated, and the component of the resist 300 adhering to the mesa portion 201 is decomposed into CO₂ by the active oxygen. The decomposed gas can be exhausted without diffusing into the ambient atmosphere. Furthermore, the deposit 310 adhering to the end of the mesa portion 201 can be peeled off by the physical force caused by the gas supplied from the air supply holes 122, and the peeled deposit 310 can be discharged to the exhaust holes 121. In this way, the resist 300 adhering to the template 200 is removed. As a result, it is possible to prevent the resist 300 from effusing into the adjacent shot region Rs during the imprinting, and it is also possible to prevent the extrusive resist 300 from being deposited on the mesa portion 201 of the template 200 and falling onto the workpiece, resulting in a contamination (e.g. a particle source).

### Fourth Aspect

Embodiments according to the first to third aspects in which the exhaust holes or the air supply holes are provided along the outer periphery of the shot region provided in the substrate periphery region of the substrate stage have been described. In such a case, the size of the shot region is assumed to be constant. In some implementations it can be difficult to cope with a change of a size of the mesa portion or an altered arrangement of the shot region on the substrate. In a fourth aspect, the description will be given with respect to an imprinting apparatus and an imprinting method capable of removing a deposit adhering to an end of a template at the time of a shot in a partial shot region even when the size of the mesa portion or the arrangement position of the shot region on the substrate is changed.

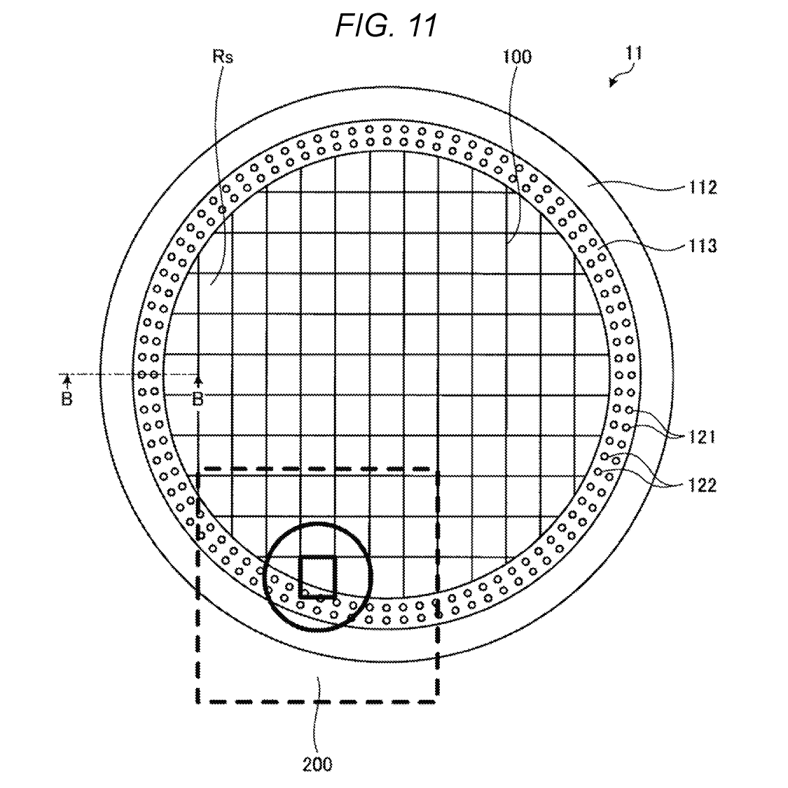

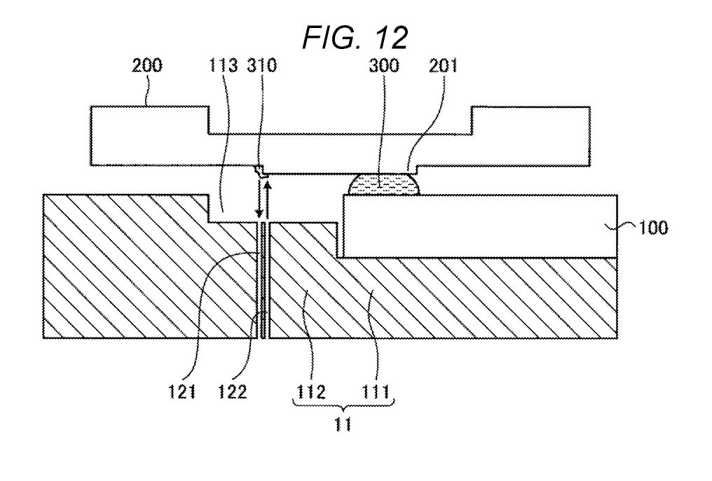

FIG. 11 is a top view illustrating some embodiments of a configuration of a substrate stage according to the fourth aspect. FIG. 12 is a partial cross-sectional view illustrating some embodiments of the configuration of the substrate stage according to the fourth aspect, and is a cross-sectional view taken along line B-B shown in FIG. 11. The substrate stage 11 is provided with a groove or recess 113 that is formed in (e.g. defined by) a substrate placing region 111 side of a substrate periphery region 112 so as to surround the substrate placing region 111. A width of the groove 113 has substantially the same size as a width of the mesa portion 201 of the template 200, for example. Air supply holes 122 and exhaust holes 121 are provided in the groove 113. Here, the air supply holes 122 are provided at predetermined intervals in a circumferential direction at a first radius distance from the center of the substrate stage 11 (substrate placing region 111), and the exhaust holes 121 are provided at predetermined intervals in the circumferential direction at a second radius distance from the center thereof. The first radius differs from the second radius. In the embodiments shown in the drawings, the second radius is illustrated to be smaller than the first radius.

The air supply holes 122 are disposed in the groove 113, and thus a gas from the air supply holes 122 can move along the groove 113. Similarly, the exhaust holes 121 are disposed in the groove 113, and thus the gas can be exhausted along the groove 113 through the exhaust holes 121. As a result, it is possible to remove a deposit 310, for example, a resist effusing into an end of the mesa portion 201 of the template 100 or a resist deposited on the end of the mesa portion 201 of the template 200, for a wide variety of shapes of the mesa portion 201 or arrangement positions of the shot region Rs on the substrate 100. According to the fourth aspect, an exhaust mechanism includes the exhaust holes 121 and an exhaust unit, and an air supply mechanism includes the air supply holes 122. Further, a resist removing mechanism includes the exhaust mechanism and the air supply mechanism.

The same components as those of the first to third aspects are denoted by the same reference numerals, and the details thereof will not be presented. In addition, the imprinting method is also similar to that described in the third aspect, so the description thereof will not be presented.

Further, the case is described herein in which the exhaust holes 121 and the air supply holes 122 are provided in the groove 113, but only the exhaust holes 121 may be provided as in the first aspect and only the air supply holes 122 may be provided as in the second aspect. The operation in the case where only the exhaust holes 121 are provided is the same as or similar to the imprinting method of the first aspect. Further, the operation in the case where only the air supply holes 122 are provided is the same as or similar to the imprinting method of the second aspect.

According to the fourth aspect, even when the shape of the mesa portion 201 or the arrangement position of the shot region Rs on the substrate 100 is changed or is variable, it is possible to realize the effect of removing the deposit 310, for example, the resist effusing into the end of the mesa portion 201 of the template 200 or the resist deposited on the mesa portion 201 of the template 200.

Embodiments according to the first to fourth aspects in which the upper surface of the substrate periphery region 112 is positioned higher in the Z-direction than the upper surface of the substrate placing region 111 by the thickness of the substrate 100 have been described, but other configurations are possible. The upper surface of the substrate periphery region 112 may have substantially the same height as the upper surface of the substrate placing region 111, for example.

### Fifth Aspect

According to a fifth aspect, description will be given with respect to an imprinting apparatus and an imprinting method which can prevent defects caused by a resist volatilized during imprinting of a template.

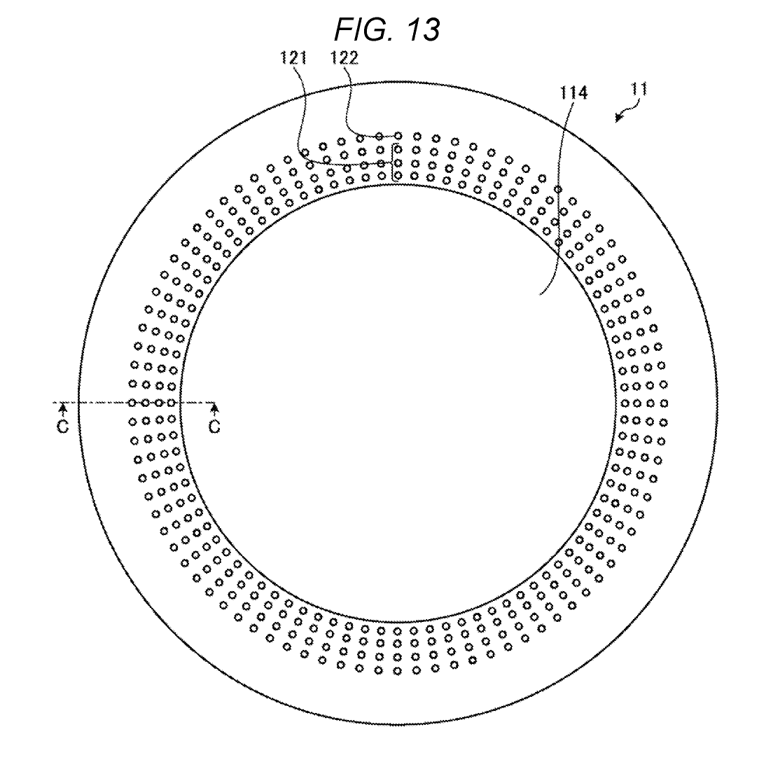

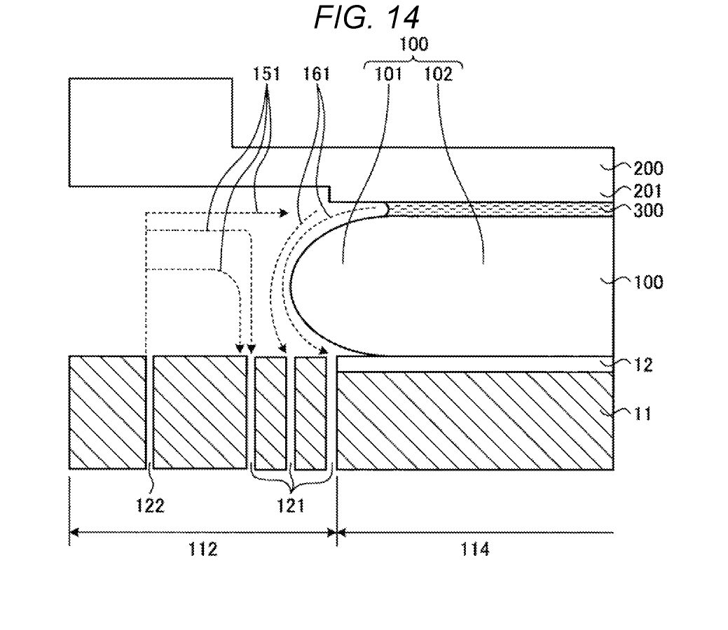

FIG. 13 is a top view illustrating some embodiments of a configuration of a substrate stage according to the fifth aspect. FIG. 14 is a partial cross-sectional view illustrating some embodiments of the configuration of the substrate stage according to the fifth aspect, and is a cross-sectional view taken along line C-C shown in FIG. 13. In the fifth aspect, a substrate stage 11 has a disk shape. That is, according to the first to fourth aspects, the substrate placing region 111 has an indented structure, but according to the fifth aspect the substrate stage 11 has a substantially flat surface, on which a substrate 100 is placed. The substrate stage 11 includes a substrate-flat-portion placing region 114 and a substrate periphery region 112. The substrate-flat-portion placing region 114 is a region on which a substantially flat rear surface of the substrate 100 is placed. As illustrated in FIG. 14, when the substrate 100 has a bevel 101 at a circumferential edge portion, the portion excluding the bevel 101 is a flat portion 102 of the substrate 100. The substrate 100 may be entirely included in the substrate-flat-portion placing region 114, or the flat portion of the substrate 100 may be included in the substrate-flat-portion placing region 114 and the bevel 101 may overflow into the substrate periphery region 112. A chuck 12 is provided in the substrate-flat-portion placing region 114.

In addition, exhaust holes 121 and air supply holes 122 are provided in the substrate periphery region 112. The exhaust holes 121 are disposed at predetermined intervals in a circumferential direction, on a circumference of a predetermined radius around the center of the substrate stage 11. In this example, three exhaust holes 121 are concentrically provided in a row. The air supply holes 122 are disposed at predetermined intervals in the circumferential direction, on the circumference of a predetermined radius around the center of the substrate stage 11. The air supply hole 122 is disposed at the outside from the exhaust hole 121. In the depicted example, one air supply hole 122 is provided. The exhaust holes 121 and the air supply hole 122 are provided to penetrate the substrate stage 11 in the thickness direction.

The exhaust holes 121 are connected to an exhaust unit such as a vacuum pump (not illustrated) on a surface opposite to the surface on which the template 200 is disposed. An exhaust speed can be set, for example, in a range of about 3 to about 30 L/min. An example of a gas may include an oxygen-containing gas such as air or oxygen. An air supply speed can be set, for example, in a range of about 3 to 30 L/min. In the fifth aspect, an exhaust mechanism includes the exhaust holes 121 and the exhaust unit, and the air supply mechanism includes the air supply hole 122. In addition, a resist removing mechanism includes the exhaust mechanism and the air supply mechanism.

The same components as those of the first to fourth aspects are denoted by the same reference numerals, and the details thereof will not be presented.

The imprinting method according to the fifth aspect is substantially the same as that described in the third aspect, so that the description thereof will not be presented. The following description will be given with reference to FIG. 14 with respect to a process of removing a resist effusing into a a mesa portion 201 of the template 200 during an imprinting process in a partial shot. In addition, a case where air is used as a gas is described as an example.

When the imprinting process that includes bringing the template 200 into contact with a resist 300 deposited on the substrate 100 to substantially fill the recess patterns of the template 200 is started, air is supplied from the air supply hole 122, and an exhaust is performed from the exhaust holes 121 at the same time. The air is supplied at a flow rate of, for example, about 20 L/min from the air supply hole 122. Further, the exhaust is performed at a flow rate of, for example, about 20 L/min from the exhaust holes 121.

The air supplied from the air supply hole 122 hits the template 200 from a substantially vertical direction (e.g. along the z-axis). On the other hand, since the exhaust is performed from the exhaust holes 121 located at the inside from the air supply hole 122, the gas hitting on the template 200 flows toward the substrate 100 along the template 200, and reaches the exhaust holes 121 along a side surface of the substrate 100, that is, the bevel 101. That is, a laminar flow 151 of the gas is formed along the surface of the template 200 and the side surface of the substrate 100 in the vicinity of the outside of the substrate 100. A part of the resist 300 is volatilized during the imprinting. The volatilized component 161 is exhausted from the exhaust holes 121 along the laminar flow 151. As a result, the volatilized component is not deposited on the mesa portion 201 of the template 200 which is not in contact with the substrate 100 via the resist 300.

In addition, after the resist is substantially filled into the recess patterns of the template 200 at the time of the imprinting process, ultraviolet rays are irradiated, but the laminar flow 151 of air also flows from the surface of the template 200 along the bevel 101 of the substrate 100. For this reason, the component 161 volatilized from the resist 300 is continuously exhausted along the laminar flow 151. When a resist 300 which can be challenging to cure by oxygen is used, the volatilized component 161 is challenging to cure by the laminar flow 151. Therefore, even when the volatilized component 161 adheres to the surface of the template 200, the volatilized component 161 is prevented from adhering to the surface of the template 200, that is, from being cured on the surface of the template 200.

Although the case of supplying the air is described above, even in the case of the oxygen-containing gas, it is possible to remove the resist effusing into the end of the mesa portion 201 of the template 200 during the imprinting process in the partial shot.

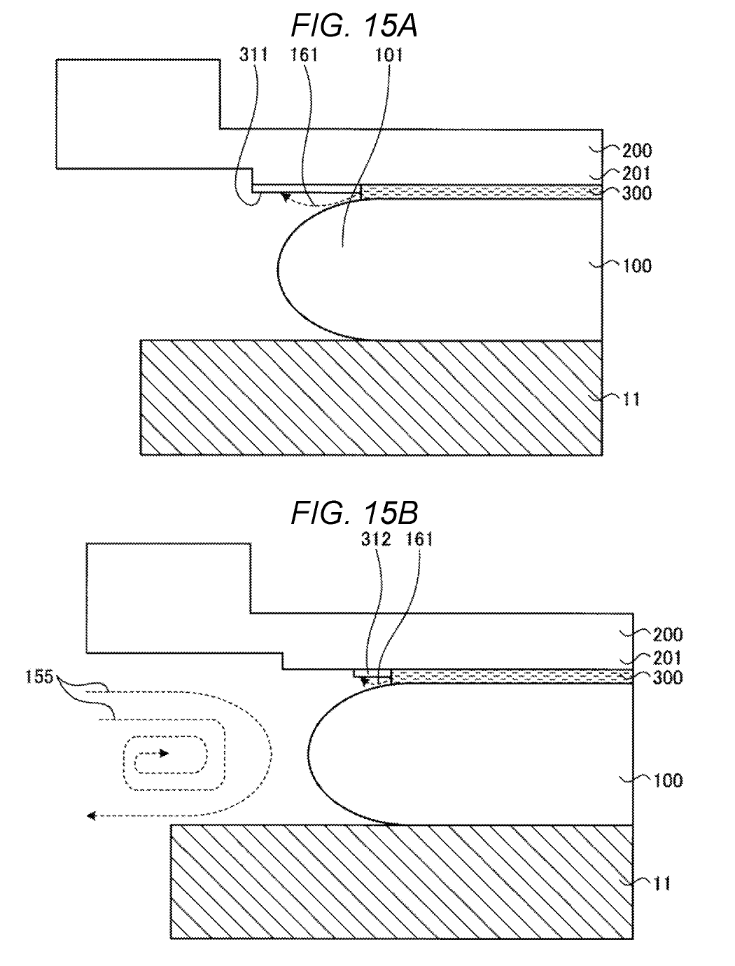

Here, advantages of the fifth aspect will be described compared with a comparative example. FIG. 15A and FIG. 15B are partial cross-sectional views schematically illustrating a stage of an imprinting process according to a comparative example, wherein FIG. 15A illustrates a first stage of a normal imprinting process, and FIG. 15B illustrates a second stage of an imprinting process wherein helium gas is purged.

As illustrated in FIG. 15A, when no gas is allowed to flow between the template 200 and the substrate stage 11, a component volatilized from a resist 300 during imprinting adheres to a mesa portion 201 of the template 200, which is not in contact with the substrate 100, via the resist 300, and forms a deposit 311. The deposit 311 is in an uncured state. Even when ultraviolet rays are irradiated in this state, since oxygen is contained in the ambient atmosphere, the deposit 311 is not cured. That is, the deposit 311 does not strongly adhere to the template 200.

When the imprinting process is performed in a next shot region Rs using the template 200, the uncured deposit 311 is peeled off from the template 200 and adheres to the substrate 100. As a result, a desired thickness of the resist 300 is not obtained at the portion to which the deposit 311 adheres, and the film thickness of the resist 300 becomes thicker by the thickness of the deposit 311, which in some cases amounts to a defect. Since the deposit 311 is peeled off at the time of the imprinting process in the next shot region Rs, it may be the case that no defect occurs in a subsequent shot region Rs.

As illustrated in FIG. 15B, when helium gas is purged between the template 200 and the substrate stage 11, a helium gas flow 155 is generated between the template 200 and the substrate stage 11. For this reason, as compared with the implementations shown in FIG. 15A, it is possible to reduce the region in which the component volatilized from the resist 300 adheres to the mesa portion 201 of the template 200, which is not in contact with the substrate 100, via the resist 300, during the imprinting process. The resist 300 slightly adheres to the mesa portion 201 of the template 200 not in contact with the substrate 100 via the resist 300.

When ultraviolet rays are irradiated in this state, the helium gas is purged, so that an oxygen concentration is low at the mesa portion 201 of the template 200 not in contact with the substrate 100 via the resist 300 and the volatilized component is cured. As a result, an adhered substance 312 is formed on the template 200. The adhered substance 312 is formed between the patterns of the template 200 or on the pattern. The adhered substance 312 is not readily peeled off from template 200, resulting in pattern defects or damage of the substrate 100 during the imprinting process in a subsequent shot region Rs.

By comparison, according to the fifth aspect, the substrate periphery region 112 of the substrate stage 11 is provided with the exhaust hole 121 and the air supply hole 122, which is disposed outside the exhaust hole 121 to supply the oxygen-containing gas. Since the gas supplied from the air supply hole 122 forms the laminar flow 151 reaching the substrate stage 11 along the bevel 101 of the substrate 100 from the upper surface of the template 200, the component 161 volatilized from the resist 300 during the imprinting is exhausted through the laminar flow 151 from the exhaust hole 121. This prevents the component 161 volatilized from the resist 300 from adhering to the mesa portion 201 of the template 200 not in contact with the substrate 100 via the resist 300. Further, even when the ultraviolet rays are irradiated, the laminar flow 151 of the oxygen-containing gas is formed along the bevel 101 of the substrate 100 from the surface of the template 200. Therefore, even when the volatilized component 161 adheres to the mesa portion 201 of the template 200 not in contact with the substrate 100 via the resist 300, the volatilized component is not cured. As a result, it is possible to realize the effect of preventing defects caused by the component adhering to the template 200 at the next and subsequent shots.

In the first to fifth aspects, description has been provided of the exhaust hole 121 or the air supply hole 122 corresponding to the target shot region Rs being selectively operated. However, in some embodiments the exhaust hole 121 or the air supply hole 122 of another shot region Rs may be separately or jointly controlled or operated.

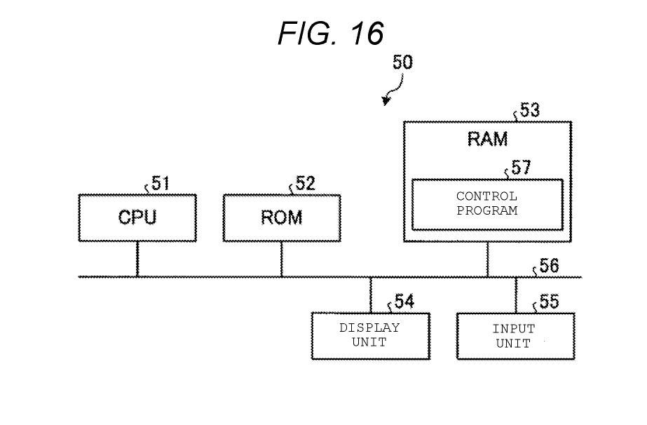

Example hardware configurations of a controller 50 of the imprinting apparatus 10 according to the first to fifth aspects will be described below. FIG. 16 is a diagram illustrating some embodiments of a hardware configuration of a controller. The controller 50 includes a CPU (Central Processing Unit) 51, a read only memory (ROM) 52, a random access memory (RAM) 53, a display unit 54, and an input unit 55. In the controller 50, the CPU 51, the ROM 52, the RAM 53, the display unit 54, and the input unit 55 are connected to each other via a bus line 56.

A control program 57 for executing the imprinting methods according to the first to fifth aspects using the imprinting apparatus 10 is stored in the ROM 52, for example. Then, the CPU 51 loads the control program 57 stored in, for example, the ROM 52 into the RAM 53 and executes the control program 57. The control program 57 is provided by being recorded in a computer-readable recording medium, such as a compact disc read only memory (CD-ROM), a flexible disk (FD), a compact disc recordable (CD-R), a digital versatile disk (DVD), a hard drive disk (HDD) or any other computer-readable recording medium in an installable or an executable file format.

As used herein, the terms “about” and “substantially” are used to describe and account for small variations. When used in conjunction with an event or circumstance, the terms “about” and “substantially” can refer to instances in which the event or circumstance occurs precisely as well as instances in which the event or circumstance occurs to a close approximation. For example, when used in conjunction with a numerical value, the terms “about” and “substantially” can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the singular terms “a,” “an,” and “the” may include plural referents unless the context clearly dictates otherwise. In the description of some embodiments, a component provided “on,” “above,” or “over” another component can encompass cases where the former component is directly on (e.g., in physical contact with) the latter component, as well as cases where one or more intervening components are located between the former component and the latter component.

While certain embodiments have been described herein, these embodiments have been presented by way of example only, and are not intended to limit the scope of the present disclosure. Indeed, the embodiments described herein may be embodied or combined in a variety of other forms; furthermore, various omissions, substitutions and changes in the form of the embodiments described herein may be made without departing from the spirit of the present disclosure. The accompanying claims and their equivalents are intended to cover such forms or modifications as would fall within the scope and spirit of the present disclosure.

What is claimed is:

1. An imprinting apparatus comprising:
a substrate holding unit having a first region configured to receive a substrate, and a second region positioned outside a periphery of a first region, the substrate holding unit comprising a resist removing mechanism comprising at least one of an exhaust mechanism or an air supply mechanism disposed in the second region;
a template holding unit configured to hold a template defining recess patterns such that the recess patterns face the substrate holding unit, and such that the template can come into contact with a resist deposited onto the substrate; and
one or more nozzles configured to discharge the resist onto the substrate.

2. The imprinting apparatus according to claim 1, wherein
the template comprises a mesa portion that defines the recess patterns, and
the resist removing mechanism is provided along a periphery of a shot region, which is positioned in the second region to correspond to a position of the mesa portion when the template is brought into contact with the resist.

3. The imprinting apparatus according to claim 1, wherein the resist removing mechanism comprises the exhaust mechanism, and the exhaust mechanism is configured to perform an exhaust process for a determined amount of time.

4. The imprinting apparatus according to claim 3, wherein the exhaust mechanism is configured to perform the exhaust process using a flow rate of about 20 liters per minute.

5. The imprinting apparatus according to claim 3, further comprising a light source configured to irradiate the resist deposited onto the substrate.

6. An imprinting method comprising:
placing a substrate on a substrate holding unit, the substrate holding unit having a first region configured to receive a substrate and a second region positioned outside a periphery of the first region;
depositing a resist onto the substrate;
causing a template defining recess patterns to contact the resist; and
using a resist removing mechanism including at least one of an exhaust mechanism or an air supply mechanism provided in the second region to remove a portion of the deposited resist that is positioned on the template facing the second region.

7. The method according to claim 6, wherein using the resist removing mechanism provided in the second region to remove the portion of the deposited resist comprises performing an exhaust process for a determined amount of time.

8. The method according to claim 7, wherein performing the exhaust process comprises using a flow rate of about 20 liters per minute.

9. The method according to claim 7, further comprising using a light source configured to irradiate the resist deposited onto the substrate.

10. The imprinting method according to claim 6, wherein
the template comprises a mesa portion that defines the recess patterns,
the resist removing mechanism is provided along a periphery of a shot region, which is positioned in the second region to correspond to a position of the mesa portion when the template is brought into contact with the resist, and
wherein the removing of the resist comprises removing a portion of the resist adhering to an outer periphery of the mesa portion.

11. An imprinting method comprising:
placing a substrate on a substrate holding unit, the substrate holding unit having a first region configured to receive a substrate and a second region positioned outside a periphery of the first region;
depositing a resist onto the substrate;
causing a template defining recess patterns that are disposed at least in part in the second region to contact the resist;
generating a laminar flow of a gas along a surface of the template and a side surface of the substrate in the second region;
substantially filling the recess patterns with the resist while maintaining the laminar flow; and
irradiating the resist filled in the recess patterns with ultraviolet rays while maintaining the laminar flow.

12. The method according to claim 11, further comprising exhausting a volatized component of the deposited resist using the laminar flow.
